(19) United States
(12) Patent Application Publication
(10) Pub. No.: US 2026/0255489 A1
(43) Pub. Date: Aug. 27, 2026

(54) DISPLAY DEVICE, METHOD OF MANUFACTURING DISPLAY DEVICE AND ELECTRONIC DEVICE INCLUDING DISPLAY DEVICE

(71) Applicant: Samsung Display Co., Ltd., Yongin-si (KR)

(72) Inventors: Jooyoung KIM, Yongin-si (KR); Young-Joo NAM, Yongin-si (KR); Youngjin PARK, Yongin-si (KR); Yuri HUR, Yongin-si (KR)

(73) Assignee: Samsung Display Co., Ltd., Yongin-si (KR)

(21) Appl. No.: 19/534,999

(22) Filed: Feb. 10, 2026

(30) Foreign Application Priority Data
Feb. 25, 2025 (KR) 10-2025-0024507

(51) Int. Cl. H05K 1/14; H05K 1/189

(52) U.S. Cl. CPC H05K 1/147; H05K 1/189; H05K 2201/10128

(57) ABSTRACT

A display device includes a display panel including a first surface and a second surface opposite to the first surface, a printed circuit board extending in a direction away from the display panel and including a third surface and a fourth surface opposite to the third surface, at least part of the third surface overlapping and connected to the first surface, a, at least one component arranged on the printed circuit board, and a flexible printed circuit board connected to the second surface and the fourth surface of the printed circuit board, and being bent in a direction away from the display panel to provide a space between the display panel and a bent portion.

### CROSS-REFERENCE TO RELATED APPLICATION

This application is based on and claims priority under 35 U.S.C. § 119 to Korean Patent Application No. 10-2025-0024507, filed on Feb. 25, 2025, in the Korean Intellectual Property Office, the disclosure of which is incorporated by reference herein in its entirety.

### BACKGROUND

### 1. Field

One or more example embodiments relate to display devices, methods of manufacturing the display device and/or electronic devices including the display device.

### 2. Description of the Related Art

As demand for display devices expands, the need for display devices that may be used for various purposes is also increasing. In line with this trend, display devices are gradually becoming larger and/or thinner, and the need for larger and/or thinner display devices and display devices with accurate and/or vivid colors is also increasing.

### SUMMARY

Some example embodiments provide display devices capable of improving space utilization within the display device.

However, example embodiments are not limited thereto.

According to one or more example embodiments, a display device may include a display panel including a first surface and a second surface opposite to the first surface, a printed circuit board including a third surface and a fourth surface opposite to the third surface, at least part of the third surface overlapping and connected to the first surface of the display panel, the printed circuit board extending in a direction away from the display panel, at least one component on the printed circuit board, and a flexible printed circuit board connected to the second surface of the display panel and the fourth surface of the printed circuit board, the flexible printed circuit board being bent in a direction away from the display panel to provide a space between the display panel and a bent portion.

In an example embodiment, the display panel may include a substrate a thin film transistor on the substrate, and a sealing member on the thin film transistor and exposing at least a portion of the thin film transistor, and the flexible printed circuit board may be connected to an exposed portion of the thin film transistor.

In an example embodiment, the display panel may include a convex portion protruding in a direction in which the flexible printed circuit board extends.

In an example embodiment, the printed circuit board may have a width wider than a width of the convex portion.

In an example embodiment, the printed circuit board may completely cover the convex portion.

In an example embodiment, a plurality of convex portions including the convex portion may be along one surface of the display panel.

In an example embodiment, the display device may further include a hinge adjacent to the printed circuit board and on one side of the display panel.

In an example embodiment, the hinge may overlap at least one of a part of one surface of the display panel or at least a part of one surface of the printed circuit board.

In an example embodiment, the printed circuit board may include an overlapping area that overlaps the display panel and a non-overlapping area that does not overlap the display panel, and the component may be placed in the non-overlapping area.

In an example embodiment, the component may be placed on the third surface of the printed circuit board.

In an example embodiment, the display device may further include a connecting portion between the printed circuit board and the flexible printed circuit board.

In an example embodiment, the connecting portion may be placed on an opposite side of the component with respect to the printed circuit board.

In an example embodiment, the display device may further include a driving integrated circuit on the second surface of the display panel and spaced apart from the flexible printed circuit board.

According to one or more example embodiments, a method of manufacturing a display device may include preparing a display panel including a first surface and a second surface opposite to the first surface, preparing a printed circuit board including at least one component arranged thereon and including a third surface and a fourth surface opposite to the third surface, preparing a flexible printed circuit board, connecting the printed circuit board to the display panel such that the third surface of the printed circuit board is connected to the first surface of the display panel and at least a portion of the third surface of the printed circuit board overlaps the first surface of the display panel, and connecting the flexible printed circuit board to the second surface of the display panel and the fourth surface of the printed circuit board while being bent in a direction away from the display panel to form a space between the display panel and the bent portion of the printed circuit board.

In an example embodiment, the preparing the display panel may include disposing a thin film transistor on a substrate and disposing a sealing member on the thin film transistor while exposing at least a portion of the thin film transistor, and the connecting the flexible printed circuit board may include connecting an exposed portion of the thin film transistor and at least a portion of the flexible printed circuit board to overlap each other.

In an example embodiment, the preparing the display panel may include forming a convex portion protruding in a direction in which the flexible printed circuit board extends.

In an example embodiment, the preparing the printed circuit board may include mounting the component on the third surface of the printed circuit board.

In an example embodiment, the printed circuit board may include an overlapping area that overlaps the display panel and a non-overlapping area that does not overlap the display panel, and the preparing the printed circuit board including mounting the component in the non-overlapping area.

In an example embodiment, the preparing the printed circuit board including placing the component may be inside the space.

In an example embodiment, the connecting the flexible printed circuit board may further include pressing the printed circuit board and the flexible printed circuit board.

According to one or more example embodiments, an electronic device may include a configured to execute by executing the at least one program, a display device configured to receive data from the processor and provide visual information, and a power supply configured to supply power to the display device, the display device may include a display panel including a first surface and a second surface opposite to the first surface, a printed circuit board including a third surface and a fourth surface opposite to the third surface, at least part of the third surface overlapping and connected to the first surface of the display panel, the printed circuit board extending in a direction away from the display panel, at least one component on the printed circuit board, and a flexible printed circuit board connected to the second surface of the display panel and the fourth surface of the printed circuit board, the flexible printed circuit board being bent in a direction away from the display panel to provide a space between the display panel and a bent portion.

### BRIEF DESCRIPTION OF THE DRAWINGS

The above and other aspects, features, and advantages of certain example embodiments of the disclosure will be more apparent from the following description taken in conjunction with the accompanying drawings in which:

FIG. 1 is a perspective view schematically illustrating a display device according to an example embodiment;

FIG. 2 is a cross-sectional view schematically illustrating an example of a cross-section taken along line I-I′ of FIG. 1;

FIG. 3 is a plan view schematically illustrating a part of the display device of FIG. 1;

FIG. 4 is a schematic diagram of an equivalent circuit illustrating an example of one pixel of the display device of FIG. 1;

FIG. 5 is a cross-sectional view schematically illustrating an example of a cross-section of a pixel in FIG. 3;

FIG. 6 is a plan view schematically illustrating a display device according to an example embodiment;

FIG. 7 is a bottom view schematically illustrating the display device of FIG. 6;

FIG. 8 is a schematic plan view of the display panel of FIG. 6;

FIG. 9 is a left side view schematically illustrating the display device of FIG. 6;

FIG. 10 is a plan view schematically illustrating a display device according to another embodiment;

FIG. 11 is a bottom view schematically illustrating the display device of FIG. 10;

FIG. 12 is a plan view schematically illustrating a display device according to another embodiment;

FIG. 13 is a plan view schematically illustrating a display device according to another embodiment;

FIG. 14 is a left side view schematically illustrating a display device according to another embodiment;

FIG. 15 is a flowchart for explaining a method of manufacturing a display device according to an example embodiment;

FIG. 16 is a block diagram of an electronic device according to an example embodiment; and

FIG. 17 is a schematic diagram of electronic devices according to various example embodiments.

### DETAILED DESCRIPTION

The present disclosure may have various modifications and example embodiments, and specific example embodiments are illustrated in the drawings and described in detail in the detailed description. The effects and features of the present disclosure and the methods for achieving them will become apparent with reference to the example embodiments described below in detail together with the drawings. However, the present disclosure is not limited to the example embodiments disclosed below and may be implemented in various forms.

In the example embodiments below, the terms such as “first” or “second” are not used in a limiting sense but are used for the purpose of distinguishing one component from another.

In the example embodiments below, singular expressions include plural expressions unless the context clearly indicates otherwise.

In the example embodiments below, terms such as “include” or “have” mean that a feature or component described in the specification is present, and do not exclude in advance the possibility that one or more other features or components may be added.

In the example embodiments below, when various components such as layers, films, regions, and plates are said to be “on” or “over” other components, this includes not only cases where they are “directly over” other components, but also cases where other components are interposed between them.

In the examples below, terms such as connect or combine do not necessarily imply a direct and/or fixed connection or combination of two members, unless the context clearly indicates otherwise, and do not exclude the presence of another member between the two members.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

In the drawings, components may be exaggerated or reduced in size for convenience of explanation. For example, the size and/or thickness of each component illustrated in the drawings are arbitrarily illustrated for convenience of explanation, and thus the present disclosure is not necessarily limited to what is illustrated.

Hereinafter, some example embodiments of the present disclosure will be described in detail with reference to the attached drawings. When describing with reference to the drawings, identical or corresponding components are given the same drawing reference numerals and redundant descriptions thereof will be omitted.

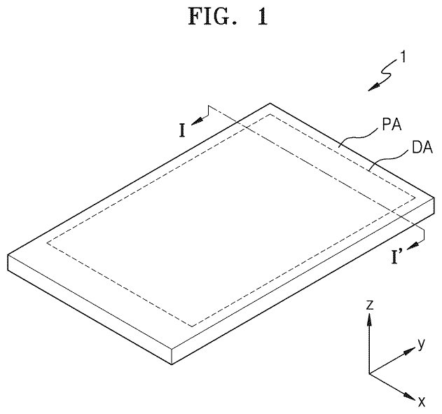

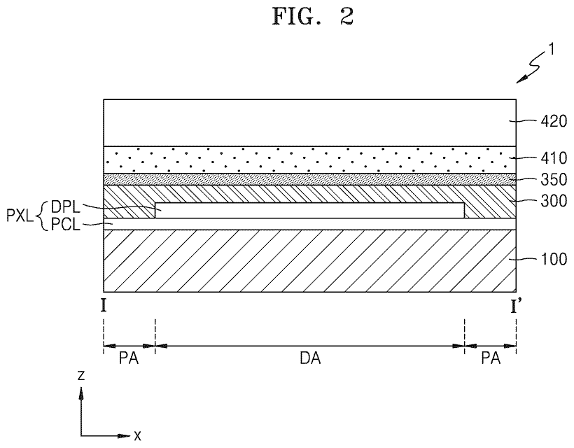

FIG. 1 is a perspective view schematically illustrating a display device according to an example embodiment, and FIG. 2 is a cross-sectional view schematically illustrating an example of a cross-section taken along line I-I′ of FIG. 1.

Referring to FIG. 1, a display device 1 according to an example embodiment may include a display area DA and a peripheral area PA. The peripheral area PA is placed around the display area DA to surround the display area DA. Various wires transmitting electrical signals to be applied to the display area DA and driving circuit may be located in the peripheral area PA. The display device 1 may provide an image by using light emitted from a plurality of pixels arranged in the display area DA. Although not illustrated, the display device 1 may be bent by including a bent area in some portion of the peripheral area PA.

The display device 1 may be a display device such as an organic light emitting display device, an inorganic light emitting display device, inorganic EL display device, or a quantum dot light emitting display device. Below, an organic light emitting display device is used as an example. The display device 1 may be implemented as various types of electronic devices such as a mobile phone, a laptop, or a smart watch.

As illustrated in FIG. 2, the display device 1 may include a substrate 100 laminated in a thickness direction (z direction), a pixel layer PXL on the substrate 100, a sealing member 300 sealing the pixel layer PXL, a light control layer 350 on the sealing member 300, a bonding layer 410 on the light control layer 350, and a functional layer 420 on the bonding layer 410.

The substrate 100 may include a glass material or a polymer resin. For example, substrate 100 may include a glass material mainly composed of SiO2 or may include various materials having flexible or bendable properties, for example, a resin such as a reinforced plastic. Although not shown, the substrate 100 may be bent by including a bent area in some portion of the peripheral area PA.

The pixel layer PXL may be placed on the substrate 100. The pixel layer PXL may include a display element layer DPL including display elements arranged for respective pixels and a pixel circuit layer PCL including pixel circuits and insulating layers arranged for respective pixels. The display element layer DPL is placed on top of the pixel circuit layer PCL, and each of a plurality of insulating layers may be placed between the pixel circuit and the display element. Some wires and insulating layers of the pixel circuit layer PCL may extend to the peripheral area PA.

The sealing member 300 may be a thin film sealing layer. The thin film sealing layer may include at least one inorganic sealing layer and at least one organic sealing layer. In case that the display device 1 includes the substrate 100 including the polymer resin and the sealing member 300 of the thin film sealing layer including the inorganic sealing layer and the organic sealing layer, a flexibility of the display device 1 may be improved.

The light control layer 350 may control a path of light emitted from the display element of the display element layer DPL and may improve a light emission efficiency of the display device 1. As described below, the light control layer 350, together with the bonding layer 410, may change the path of light emitted from the display element to increase a light extraction efficiency of the display device 1.

The bonding layer 410 bonds the functional layer 420 located above the sealing member 300 to a layer below it, for example, the light control layer 350. Additionally, the bonding layer 410 has a refractive index greater than that of the light control layer 350, thereby improving the light extraction efficiency of the display device 1.

The functional layer 420 may include a polarizing layer. The polarizing layer may transmit light that vibrates in a same direction as a polarization axis of the light emitted from the display element of the display element layer DPL and absorb or reflect light that vibrates in other directions. Additionally, the functional layer 420 may further include an optical film, window, or the like for reflecting external light.

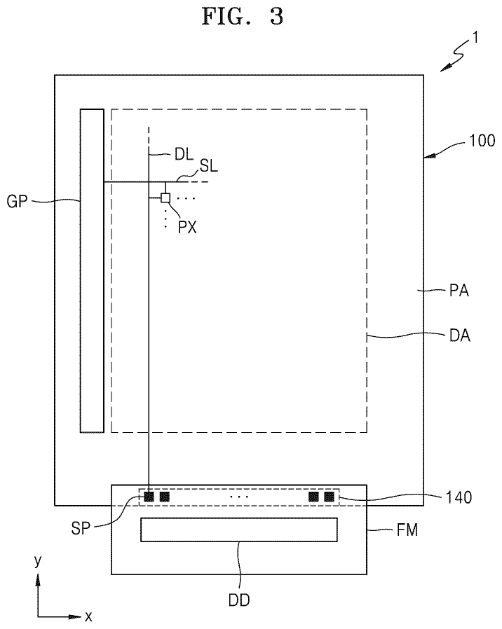

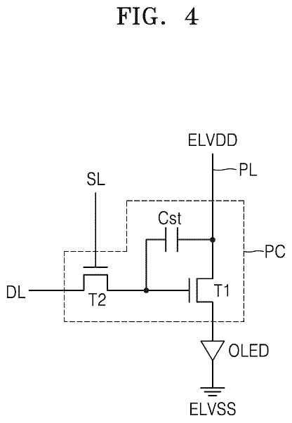

FIG. 3 is a plan view schematically illustrating a part of the display device of FIG. 1, and FIG. 4 is a schematic diagram of an equivalent circuit illustrating an example of one pixel of the display device of FIG. 1.

Referring to FIG. 3, the substrate 100 may include a display area DA and a peripheral area PA. The peripheral area PA may be located outside the display area DA and surround the display area DA.

A plurality of pixels PXs may be arranged in a pattern in a first direction (x direction, row direction) and a second direction (y direction, column direction) in the display area DA on the substrate 100.

A scan driver GP providing a scan signal to each pixel PX, a data driver DD providing a data signal to each pixel PX, and main power wires (not illustrated) providing a first power voltage (ELVDD, see FIG. 4) and a second power voltage (ELVSS, see FIG. 4) may be arranged in the peripheral area PA on the substrate 100. A pad portion 140 on which a plurality of signal pads SP connected to a data line DL are arranged may be located in the peripheral area PA on the substrate 100.

The scan driver GP may include an oxide semiconductor TFT gate driver circuit (OSG) or an amorphous silicon TFT gate driver circuit (ASG). In FIG. 3, the scan driver GP is illustrated as an example of being placed adjacent to one side of the substrate 100. Depending on some example embodiments, however, the scan driver GP may be placed adjacent to each of two facing sides of the substrate 100.

FIG. 3 illustrates a chip on film (COF) method in which the data driver DD is placed on a film (FM) electrically connected to signal pads SPs placed on the substrate 100. In another example embodiment, the data driver DD may be placed directly on the substrate 100 in a chip on glass (COG) method or a chip on plastic (COP) method. The data driver DD may be electrically connected to a flexible printed circuit board (FPCB).

Referring to FIG. 4, one pixel PX may include a pixel circuit PC and an organic light-emitting diode OLED electrically connected to the pixel circuit PC.

For example, the pixel circuit PC may be connected to a display element, for example, the organic light-emitting diode OLED. The pixel circuit PC may include a driving transistor T1, a switching transistor T2, and a storage capacitor Cst. The organic light-emitting diode OLED may emit red light, green light, or blue light, or may emit red light, green light, blue light, or white light.

The switching transistor T2 is connected to a scan line SL and the data line DL and may transmit the scan signal input from the scan line SL or the data signal or a data voltage input from the data line DL based on the switching voltage to the driving transistor T1. The storage capacitor Cst is connected to the switching transistor T2 and a driving voltage line PL, and may store a voltage corresponding to a difference between a voltage received from the switching transistor T2 and the first power voltage ELVDD supplied to the driving voltage line PL.

The driving transistor T1 is connected to the driving voltage line PL and the storage capacitor Cst and may control a driving current flowing through the organic light-emitting diode OLED from the driving voltage line PL in response to a voltage value stored in the storage capacitor Cst. The organic light-emitting diode OLED may emit light with a certain brightness depending on the driving current. A counter electrode (or common electrode) of the organic light-emitting diode OLED may be supplied with the second power voltage ELVSS.

Although FIG. 4 illustrates that the pixel circuit PC includes two transistors and one storage capacitor, the pixel circuit PC may include three, four, five or more transistors. Additionally, the pixel circuit PC may contain two or more capacitors.

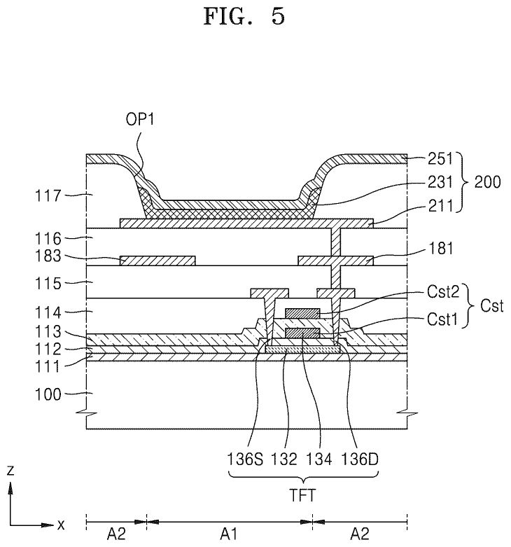

FIG. 5 is a cross-sectional view schematically illustrating an example of a cross-section of a pixel in FIG. 3.

Referring to FIG. 5, a buffer layer 111 may be formed on the substrate 100 to block or prevent impurities from penetrating into a semiconductor layer of a thin film transistor.

The substrate 100 may include various materials such as glass, metal, or plastic. In an example embodiment, the substrate 100 may be a flexible substrate and may include a polymer resin, such as polyethersulphone (PES), polyacrylate (PAR), polyetherimide (PEI), polyethylenenaphthalate (PEN), polyethyleneterephthalate (PET), polyphenylenesulfide (PPS), polyallylate, polyimide (PI), polycarbonate (PC), or cellulose acetate propionate (CAP).

The buffer layer 111 may include an inorganic insulating material such as silicon nitride or silicon oxide and may be a single layer or multiple layers.

A thin film transistor TFT, a capacitor Cst, and an organic light-emitting diode 200 electrically connected to the thin film transistor TFT may be placed on the substrate 100. The organic light-emitting diode 200 being electrically connected to the thin film transistor TFT may mean that a pixel electrode 211 is electrically connected to the thin film transistor TFT. The thin film transistor TFT may be the driving transistor T1 of FIG. 4.

The thin film transistor TFT may include a semiconductor layer 132, a gate electrode 134, a source electrode 136S, and a drain electrode 136D. The semiconductor layer 132 may include an oxide semiconductor material. The semiconductor layer 132 may include amorphous silicon, polycrystalline silicon, or organic semiconductor material. The gate electrode 134 may include at least one material selected from a group consisting of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), and may be formed as a single layer or multiple layers, taking into consideration adhesion to adjacent layers, surface flatness of layers laminated thereon, processability, or the like.

A gate insulating layer 112 including an inorganic material such as silicon oxide, silicon nitride, and/or silicon oxynitride may be interposed between the semiconductor layer 132 and the gate electrode 134. A first interlayer insulating layer 113 and a second interlayer insulating layer 114 including an inorganic material such as silicon oxide, silicon nitride, and/or silicon oxynitride may be disposed between the gate electrode 134, the source electrode 136S, and the drain electrode 136D. Each of the source electrode 136S and the drain electrode 136D may be electrically connected to the semiconductor layer 132 through contact holes formed in the gate insulating layer 112, the first interlayer insulating layer 113, and the second interlayer insulating layer 114.

The source electrode 136S and the drain electrode 136D include one or more materials selected from a group consisting of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), and may be formed as a single layer or multiple layers.

The capacitor Cst includes a lower electrode Cst1 and an upper electrode Cst2 that overlap each other, and the first interlayer insulating layer 113 is located between them. The capacitor Cst may be overlapped with the thin film transistor TFT. In FIG. 5, it is illustrated that the gate electrode 134 of the thin film transistor TFT is the lower electrode Cst1 of the capacitor Cst. As another example embodiment, the capacitor Cst may not overlap the thin film transistor TFT. The capacitor Cst may be covered with the second interlayer insulating layer 114.

The pixel circuit including the thin film transistor TFT and the capacitor Cst may be covered with a first insulating layer 115 and a second insulating layer 116. Each of the first insulating layer 115 and the second insulating layer 116 may be a planarizing insulating layer and/or may be an organic insulating layer. The first insulating layer 115 and the second insulating layer 116 may include an organic insulating material, such as a general-purpose polymer (e.g., polymethylmethacrylate (PMMA) or polystyrene (PS)), a polymer derivative having a phenol group, an acrylic polymer, an imide polymer, an aryl ether polymer, an amide polymer, a fluorinated polymer, a p-xylene polymer, a vinyl alcohol polymer, or a blend thereof. In an example embodiment, the first insulating layer 115 and the second insulating layer 116 may include polyimide.

The display element, for example the organic light-emitting diode 200, may be placed on top of the second insulating layer 116. The organic light-emitting diode 200 may include a pixel electrode 211, an intermediate layer 231, and a counter electrode 251.

The pixel electrode 211 is arranged on the second insulating layer 116 and may be connected to the thin film transistor TFT through a connection electrode 181 on the first insulating layer 115. A wire 183, such as the data line DL and the driving voltage line PL, may be placed on the first insulating layer 115.

The pixel electrode 211 may include conductive oxide such as indium tin oxide (ITO), indium zinc oxide (IZO), zinc oxide (ZnO), indium oxide (In2O3), indium gallium oxide (IGO), or aluminum zinc oxide (AZO). In another example embodiment, the pixel electrode 211 may include a reflective film including silver (Ag), magnesium (Mg), aluminum (Al), platinum (Pt), palladium (Pd), gold (Au), nickel (Ni), neodymium (Nd), iridium (Ir), chrome (Cr), or compounds thereof. In another example embodiment, the pixel electrode 211 may further include a film including ITO, IZO, ZnO or In2O3 and may be formed on/under the reflective film.

A third insulating layer 117 may be placed on the second insulating layer 116. The third insulating layer 117 is a pixel definition film that defines the pixel, may cover an edge of the pixel electrode 211 and may have a first opening OP1 that exposes a part of the pixel electrode 211. The first opening OP1 may correspond to a first area A1. The third insulating layer 117 may reduce or prevent arcing from occurring at the edge of the pixel electrode 211 by increasing a distance between the edge of the pixel electrode 211 and the counter electrode 251. The third insulating layer 117 may be formed of or include an organic material such as polyimide (PI), hexamethyldisiloxane (HMDSO), or the like.

The intermediate layer 231 includes an emitting layer. The emitting layer may include a relatively high molecular weight or low relatively molecular weight organic material that emits light of a given color. In an example embodiment, the intermediate layer 231 may include a first functional layer disposed below the emitting layer and/or a second functional layer disposed above the emitting layer. The first functional layer and/or the second functional layer may include a single layer spanning the plurality of pixel electrodes 211 or may include a layer patterned to correspond to each of the plurality of pixel electrodes 211.

The first functional layer may be a single layer or multiple layers. For example, in case that the first functional layer is formed of or include a relatively high molecular weight material, the first functional layer may be a hole transport layer (HTL) with a single layer structure, and may include poly-(3,4)-ethylene-dihydroxy thiophene (PEDOT) or polyaniline (PANI). In case that the first functional layer is formed of or include a relatively low molecular weight material, the first functional layer may include a hole injection layer (HIL) and the hole transport layer (HTL).

The second functional layer may not always be present or available. For example, in case that the first functional layer and the emitting layer are formed of or include the relatively high molecular weight material, it is desirable to form the second functional layer so that characteristics of the organic light-emitting diode are improved. The second functional layer may be a single layer or multiple layers. The second functional layer may include an electron transport layer (ETL) and/or an electron injection layer (EIL).

The counter electrode 251 is placed facing the pixel electrode 211, and the intermediate layer 231 is placed between the counter electrode 251 and the pixel electrode 211. The counter electrode 251 may include a conductive material having a low work function. For example, the counter electrode 251 may include a (semi)transparent layer including silver (Ag), magnesium (Mg), aluminum (Al), platinum (Pt), palladium (Pd), gold (Au), nickel (Ni), neodymium (Nd), iridium (Ir), chrome (Cr), lithium (Li), calcium (Ca) or an alloy thereof. In some example embodiments, the counter electrode 251 may further include a layer such as ITO, IZO, ZnO or In2O3 on the (semi)transparent layer including the aforementioned material.

The counter electrode 251 may be placed on top of the intermediate layer 231 and the third insulating layer 117. The counter electrode 251 may be integrally formed across a plurality of organic light-emitting diodes 200 in the display area DA, so as to face a plurality of pixel electrodes 211.

Below, display devices according to some example embodiments will be described in detail. Hereinafter, for convenience of explanation, the same contents as previously described or contents that can be easily applied by a person with common knowledge in the technical field to which the present disclosure belongs will be omitted or briefly described.

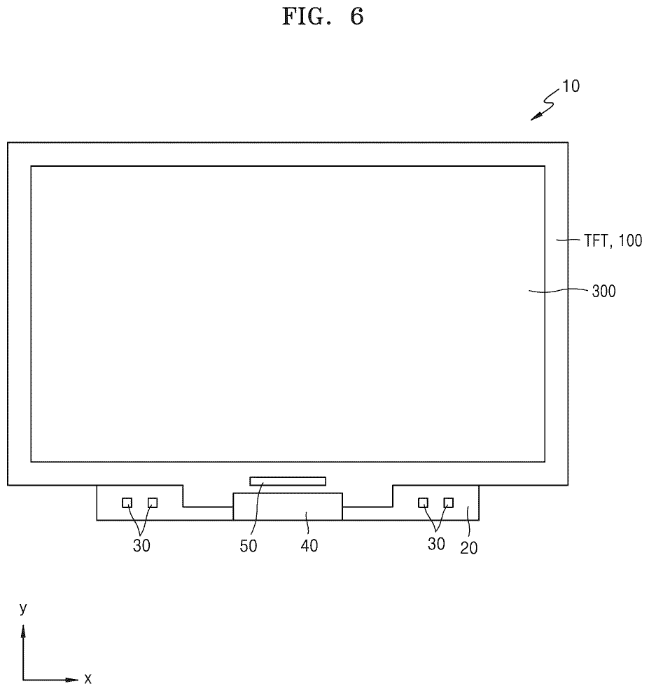

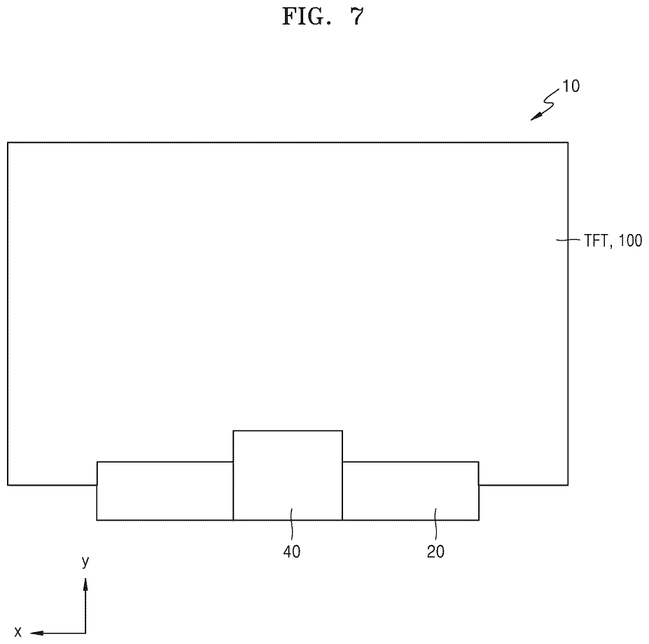

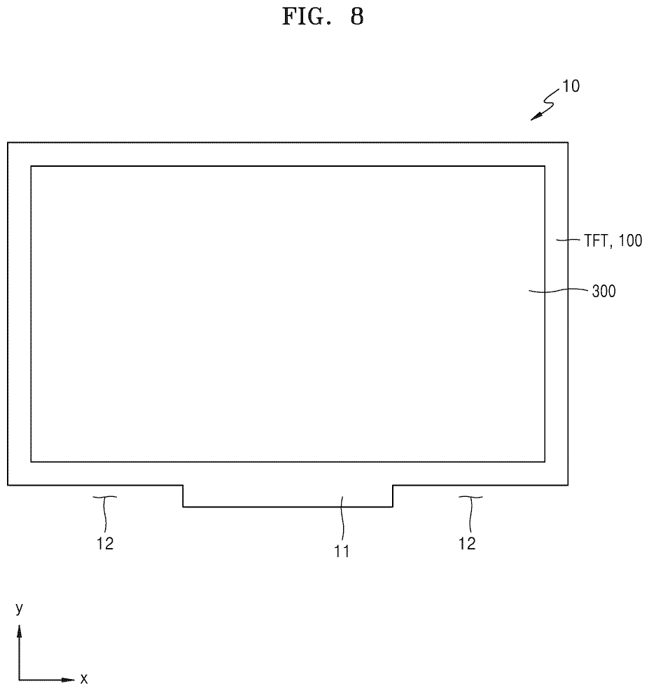

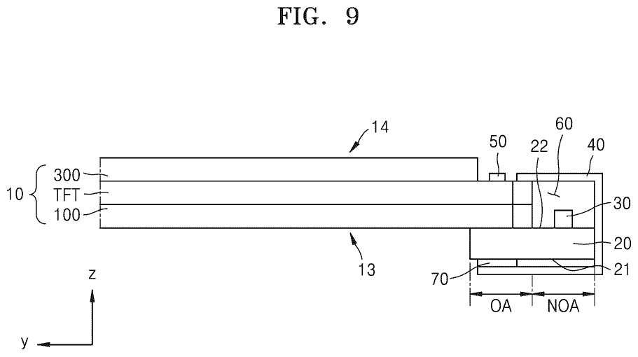

FIG. 6 is a plan view schematically illustrating a display device according to an example embodiment, and FIG. 7 is a bottom view schematically illustrating the display device of FIG. 6. FIG. 8 is a schematic plan view of the display panel of FIG. 6, and FIG. 9 is a left side view schematically illustrating the display device of FIG. 6.

Referring to FIGS. 6 to 9, the display device 1 according to an example embodiment may include a display panel 10, a printed circuit board 20, at least one component 30, and a flexible printed circuit board 40.

The display panel 10 may include the display area DA and the peripheral area PA. At this time, the pixels PXs may be placed in the display area DA. The display panel 10 may provide images by using light emitted from the pixels. Each pixel PX may emit light by using a display element. In an example embodiment, the display element may be an organic light-emitting diode OLED. In an example embodiment, each pixel PX may emit red light, green light, or blue light. As another example, each pixel PX may emit red light, green light, blue light, or white light.

The display panel 10 may include a first surface 13 and a second surface 14. The first surface 13 and the second surface 14 may refer to opposite surfaces. That is, the second surface 14 may be a surface located opposite the first surface 13.

In an example embodiment, the display panel 10 may include a substrate 100, a thin film transistor TFT, and a sealing member 300. Here, the substrate 100, the thin film transistor TFT, and the sealing member 300 may be the substrate 100, the thin film transistor TFT, and the sealing member 300 described with reference to FIGS. 1 to 5.

However, it is not limited thereto, and the display panel 10 may further include additional components to perform other functions. For example, the display panel 10 may further include various configurations to change the path of light and/or improve light extraction efficiency. For example, although not illustrated, the polarizing layer may be further placed on the sealing member 300.

The thin film transistor TFT may be placed on the substrate 100. The sealing member 300 may be placed on the thin film transistor TFT.

In an example embodiment, the thin film transistor TFT may be low-temperature polycrystalline silicon (LTPS).

In an example embodiment, the sealing member 300 may be positioned on the thin film transistor TFT such that at least a portion of the thin film transistor TFT is exposed. For example, the sealing member 300 may be formed to have an area narrower than an area of the thin film transistor TFT. For example, referring to FIG. 9, the sealing member 300 may be formed shorter than the thin film transistor TFT in one direction (y-axis direction of FIG. 9).

In this case, the first surface 13 may mean a bottom surface of the substrate 100 among surfaces of the display panel 10. Additionally, the second surface 14 may mean a top surface of the sealing member 300 and the exposed top surface of the thin film transistor TFT among surfaces of the display panel 10.

In an example embodiment, the display panel 10 may include a convex portion 11 and a concave portion 12.

The convex portion 11 may be a portion formed by protruding in one direction from one side of the display panel 10. For example, the convex portion 11 may protrude along a direction in which the flexible printed circuit board 40 extends, as described below. The concave portion 12 may mean a space formed adjacent to the convex portion 11 by forming the convex portion 11.

In an example embodiment, the convex portion 11 may be a portion where the substrate 100 and the thin film transistor TFT protrude, as illustrated in FIG. 8. Accordingly, a distance from the sealing member 300 to an end of the display panel 10 may be longer at a portion where the convex portion 11 is formed than at a portion where the concave portion 12 is formed.

The printed circuit board 20 may be connected to the first surface 13 of the display panel 10.

The printed circuit board 20 may include an upper surface 21 and a lower surface 22. The upper surface 21 and the lower surface 22 may mean surfaces located on opposite sides. That is, the lower surface 22 may be a surface located opposite the upper surface 21.

The printed circuit board 20 may be connected so that the lower surface 22 is in contact with the first surface 13 of the display panel 10.

In an example embodiment, the lower surface 22 of the printed circuit board 20 may be positioned such that at least a portion thereof overlaps the first surface 13 of the display panel 10.

The printed circuit board 20 is arranged so that at least a portion thereof overlaps the first surface 13 of the display panel 10 and may extend in a direction away from the display panel 10. Here, a portion of the printed circuit board 20 extending away from the display panel 10 may not overlap with the display panel 10.

Accordingly, the printed circuit board 20 may include an overlapping area OA that overlaps the display panel 10 and a non-overlapping area NOA that does not overlap the display panel 10. Therefore, the printed circuit board 20 may be connected to the display panel 10 while overlapping the display panel 10 by the amount of the overlapping area.

At least one component 30 may be placed on the printed circuit board 20.

In an example embodiment, the component 30 may be placed on the lower surface 22 of the printed circuit board 20. That is, as illustrated in FIG. 9, at least one component 30 may be placed on a same side (z-axis side in FIG. 9) as the display panel 10 with respect to the printed circuit board 20.

The component 30 refers to parts mounted on the printed circuit board 20, and may be a connector, a control processor, a power integrated circuit, memory, or the like, but is not limited thereto. Anything that may be mounted on the printed circuit board 20 and perform various functions may be included in the component 30.

In an example embodiment, the printed circuit board 20 may have a width wider than a width of the convex portion 11. For example, the printed circuit board 20 may overlap the first surface 13 of the display panel 10 and may be formed wider than the convex portion 11 in a width direction (x-axis direction in FIG. 6).

In an example embodiment, the printed circuit board 20 may be positioned to entirely cover the convex portion 11. For example, the printed circuit board 20 may be formed so that at least a portion thereof overlaps the first surface 13 of the display panel 10 and may be formed to extend to a position that protrudes further than the convex portion 11. In other words, the non-overlapping area NOA of the printed circuit board 20 may be formed across both the concave portion 12 and the convex portion 11.

In an example embodiment, the component 30 may be placed in the non-overlapping area NOA. That is, the overlapping area OA of the lower surface 22 of the printed circuit board 20 may be connected to the display panel 10, and the component 30 may be placed on the non-overlapping area NOA.

In an example embodiment, the component 30 may be mounted or placed at a position corresponding to the concave portion 12 of the non-overlapping area NOA of the display panel 10.

The flexible printed circuit board 40 may be connected to the display panel 10 and the printed circuit board 20.

One side of the flexible printed circuit board 40 may be connected to the second surface 14 of the display panel 10, and another side thereof may be connected to the upper surface 21 of the printed circuit board 20.

As one example, one side of the flexible printed circuit board 40 may be connected such that at least a portion thereof overlaps the convex portion 11 of the display panel 10.

The flexible printed circuit board 40 is connected to the display panel 10 and the printed circuit board 20, and a portion of the flexible printed circuit board 40 between the display panel 10 and the printed circuit board 20 may be bent. Referring to FIG. 9, the flexible printed circuit board 40 may be bent in a direction away from the display panel 10 (-direction of y-axis in FIG. 9). In the drawing, the flexible printed circuit board 40 is illustrated as being roughly vertically bent However, example embodiments are not limited thereto. In some example embodiments, the flexible printed circuit board 40 may be bent in a curved manner.

By bending the flexible printed circuit board 40, a space 60 may be provided between the display panel 10 and the bent portion of the flexible printed circuit board 40. For example, one side of the flexible printed circuit board 40 may be connected to the second surface 14 of the display panel 10, extended in a direction away from the display panel 10, bent in a direction toward the printed circuit board 20, and extended toward the upper surface 21 of the printed circuit board 20 to be connected to the upper surface 21 of the printed circuit board 20. Accordingly, as the flexible printed circuit board 40 extends away from the display panel 10, the space 60 is provided between the display panel 10 and the bent portion of the flexible printed circuit board 40.

In an example embodiment, referring to FIG. 9, the space 60 may be surrounded by the display panel 10, the flexible printed circuit board 40, and the printed circuit board 20. In other words, the space 60 may be defined by a side of the display panel 10, an inner side of the flexible printed circuit board 40, and the non-overlapping area NOA of the lower surface 22 of the printed circuit board 20.

As an optional example embodiment, the component 30 may be placed in the non-overlapping area NOA of the lower surface 22 of the printed circuit board 20, at least one of which may be placed inside the space 60.

Therefore, the non-overlapping area NOA of the lower surface 22 of the printed circuit board 20 may be placed to overlap the space 60, and the component 30 may also be placed in the non-overlapping area NOA.

In an example embodiment, the flexible printed circuit board 40 may be connected to an exposed portion of the thin film transistor TFT. That is, the flexible printed circuit board 40 may be connected to the exposed portion of the thin film transistor TFT at a position spaced apart from the sealing member 300 by a certain distance.

In an example embodiment, a driving integrated circuit 50 may be further placed on the display panel 10. The driving integrated circuit 50 is connected to the display panel 10 and may drive the display device 1. For example, the driving integrated circuit 50 may be connected to the display panel 10 via a chip on glass (COG) method, but is not limited thereto, According to some example embodiments, the driving integrated circuit 50 may be connected to the display panel 10 via a chip on plastic (COP) method, ultrasonic bonding method, or the like.

In an example embodiment, the driving integrated circuit 50 may be placed on the second surface 14 of the display panel 10. For example, the driving integrated circuit 50 may be placed on the exposed portion of the thin film transistor TFT. The driving integrated circuit 50 may be arranged on the second surface 14 of the display panel 10 and may be spaced apart from the flexible printed circuit board 40.

In an example embodiment, a connecting portion 70 may be further arranged between the printed circuit board 20 and the flexible printed circuit board 40. The connecting portion 70 may be a portion that physically and electrically connects the printed circuit board 20 and the flexible printed circuit board 40.

As an optional example embodiment, the connecting portion 70 may be a connecting film. That is, the printed circuit board 20 and the flexible printed circuit board 40 may be connected in a film on board (FOB) method. Accordingly, the connecting portion 70 may be placed between the printed circuit board 20 and the flexible printed circuit board 40 to perform the function of the driving circuit.

For this purpose, the printed circuit board 20 and the flexible printed circuit board 40 may be connected by pressing.

In an example embodiment, the connecting portion 70 may be positioned on the opposite side of the component 30 with respect to the printed circuit board 20. That is, as illustrated in FIG. 9, the connecting portion 70 is arranged on the upper surface 21 of the printed circuit board 20 and connected to the flexible printed circuit board 40 and the component 30 is arranged on the lower surface 22 of the printed circuit board 20 in the non-overlapping area NOA so that the component 30 may not interfere with the connection between the printed circuit board 20 and the flexible printed circuit board 40.

In this way, in the case of the display device 1, the flexible printed circuit board 40 is arranged to form the space 60, and the printed circuit board 20 is connected so that at least a portion thereof overlaps the display panel 10, so that a dead space created by the connection between each component may be efficiently utilized, and/or an overall thickness of the device may be reduced.

In addition, in the case of the display device 1, a part of the exposed portion of the display panel 10 is covered by the printed circuit board 20 and the flexible printed circuit board 40, so that damage to the display panel 10 due to external impact is prevented or reduced.

However, it is not limited thereto, and the display device 1 may have various additional effects through the above-described configuration.

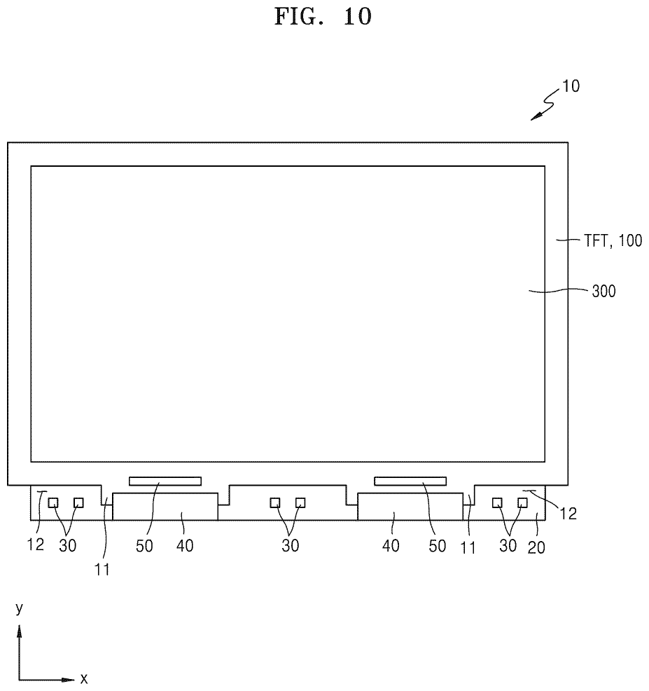

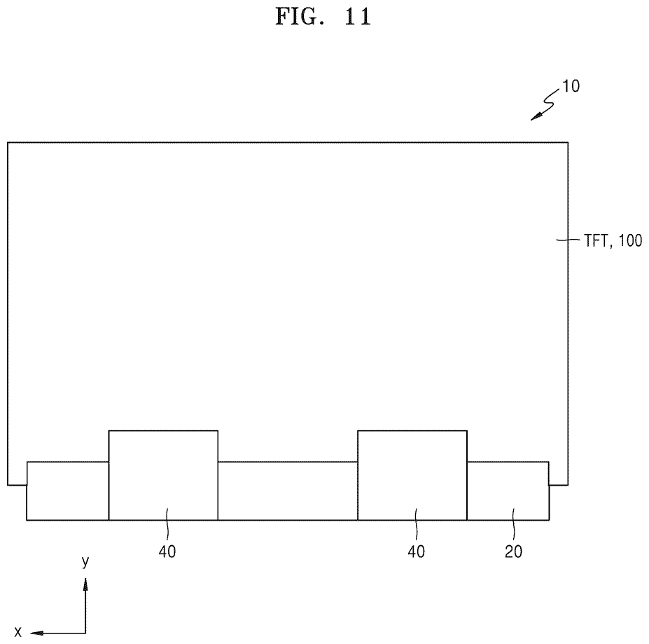

FIG. 10 is a plan view schematically illustrating a display device according to another example embodiment, and FIG. 11 is a bottom view schematically illustrating the display device of FIG. 10.

Hereinafter, for convenience of explanation, the same contents as previously described or contents that can be easily applied by a person with common knowledge in the technical field to which the present disclosure belongs will be omitted or briefly described.

Referring to FIGS. 10 and 11, the display panel 10 may include a plurality of convex portions 11.

In an example embodiment, a plurality of convex portions 11 may be formed along one side of the display panel 10.

The convex portion 11 may be formed to protrude in one direction from one side of the display panel 10. Accordingly, concave portions 12 may be formed between adjacent convex portions 11 and on outer sides of the convex portions 11 at both end edges.

In an example embodiment, the printed circuit board 20 may be arranged to cover all of the plurality of convex portions 11. For example, the printed circuit board 20 may be formed such that at least a portion thereof overlaps the first surface 13 of the display panel 10 and may be formed to extend to a position that protrudes further than the plurality of convex portions 11. In other words, the non-overlapping area NOA of the printed circuit board 20 may be formed over the concave portion 12 and the convex portion 11.

In an example embodiment, the flexible printed circuit board 40 may be connected such that at least a portion thereof overlaps the convex portion 11 of the display panel 10, for example, a plurality of flexible printed circuit boards 40 may be arranged to be connected to the convex portions 11, corresponding to the plurality of convex portions 11, respectively.

In an example embodiment, a driving integrated circuit 50 may be further placed on the display panel 10. For example, in case that the plurality of flexible printed circuit boards 40 are arranged on the display panel 10 to correspond to the plurality of convex portions 11, respectively, a plurality of driving integrated circuits 50 may be arranged on the display panel 10 to correspond to the plurality of flexible printed circuit boards 40, respectively.

In this way, the display device 1 has the plurality of convex portions 11, so that the plurality of flexible printed circuit boards 40 may be connected to the display panel 10 as needed.

However, it is not limited thereto, and the display device 1 may have various additional effects through the above-described configuration.

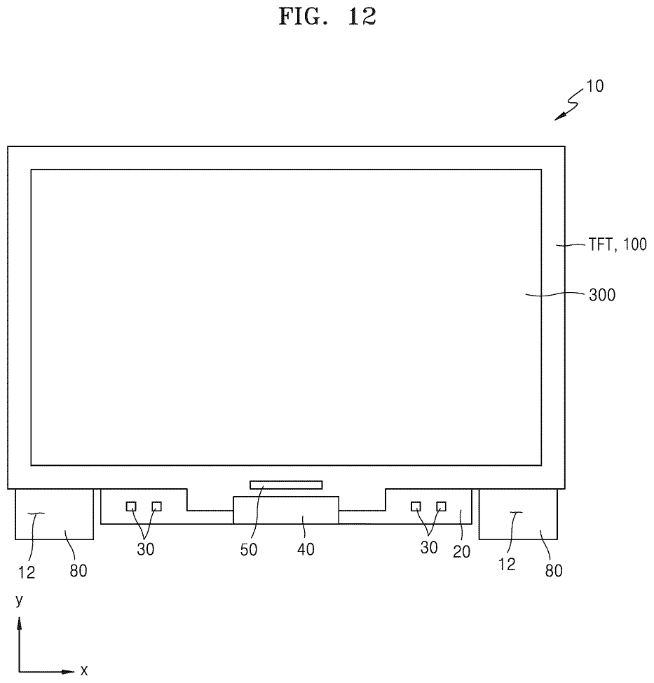

FIG. 12 is a plan view schematically illustrating a display device according to another example embodiment.

Hereinafter, for convenience of explanation, the same contents as previously described or contents that can be easily applied by a person with common knowledge in the technical field to which the present disclosure belongs will be omitted or briefly described.

Referring to FIG. 12, the display device 1 according to an example embodiment may further include a hinge 80.

The hinge 80 may be configured to allow the display panel 10 to rotate relative to another mechanical configuration when the display panel 10 is connected to that mechanical configuration.

The hinge 80 may be positioned adjacent to the printed circuit board 20 on one side of the display panel 10.

As one example, the hinge 80 may overlap a portion of one surface of the display panel 10. Although not specifically illustrated in FIG. 12, the hinge 80 may also overlap a portion of one surface of the printed circuit board 20. In other words, the hinge 80 may be arranged on the concave portion 12 of the display panel 10 so as to overlap at least one of a portion of the display panel 10 or at least a portion of the printed circuit board 20.

In this way, in the case of the display device 1, at least a part of an exposed portion of the display panel 10 is covered by the hinge 80 as well as the printed circuit board 20 and the flexible printed circuit board 40., Thus, damage to the display panel 10 due to external impact is prevented or reduced.

In addition, in the case of the display device 1, the hinge 80 is placed adjacent to the printed circuit board 20. so that a space desired for placing the hinge 80 may be reduced, and thus an overall thickness and/or dead space of the device may be reduced.

However, it is not limited thereto, and the display device 1 may have various additional effects through the above-described configuration.

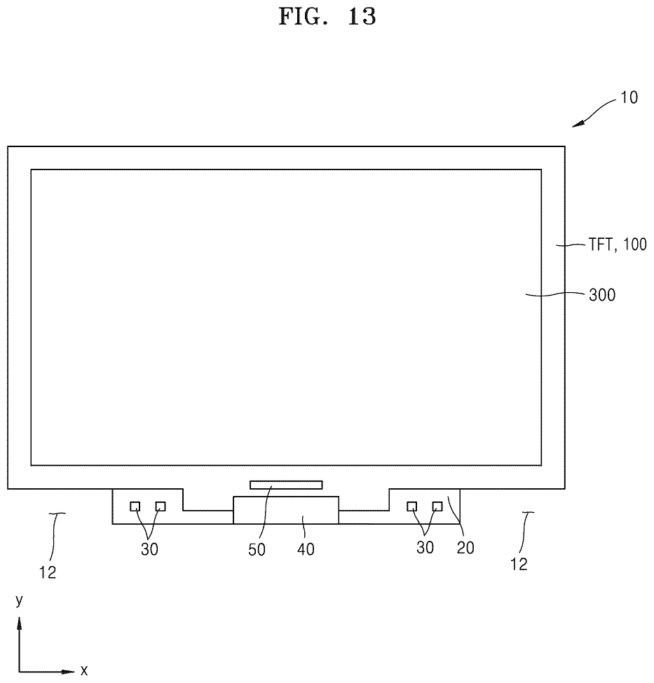

FIG. 13 is a plan view schematically illustrating a display device according to another example embodiment.

Hereinafter, for convenience of explanation, the same contents as previously described or contents that can be easily applied by a person with common knowledge in the technical field to which the present disclosure belongs will be omitted or briefly described.

Referring to FIG. 13, a width (x-axis direction of FIG. 13) of the printed circuit board 20 of the display device 1 may be formed in various ways.

For example, if additional components need to be placed on either side of the printed circuit board 20, the printed circuit board 20 may be formed with a narrower width.

As another example, if the number of components 30 mounted on the printed circuit board 20 increases, the width of the printed circuit board 20 may be formed wider.

In this case, the printed circuit board 20 may be arranged to overlap at least partly with the display panel 10 and may include an overlapping area OA and a non-overlapping area NOA. Additionally, the component 30 may be placed in the non-overlapping area NOA.

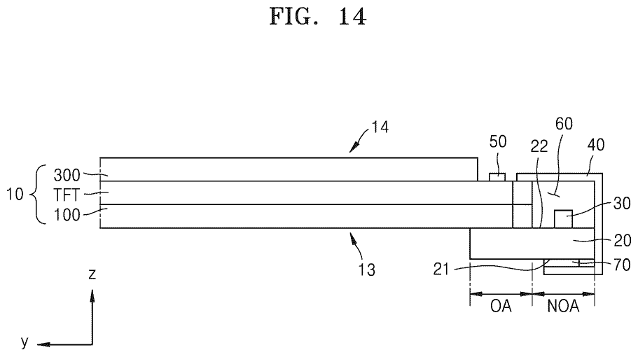

FIG. 14 is a left side view schematically illustrating a display device according to another example embodiment.

Hereinafter, for convenience of explanation, the same contents as previously described or contents that can be easily applied by a person with common knowledge in the technical field to which the present disclosure belongs will be omitted or briefly described.

Referring to FIG. 14, in the display device 1 according to an example embodiment, the position at which the flexible printed circuit board 40 and the printed circuit board 20 are connected may be adjusted.

In an example embodiment, the flexible printed circuit board 40 may be connected to the printed circuit board 20 at a relatively distant location from the display panel 10. In this case, the connecting portion 70 may be placed at the connecting portion of the flexible printed circuit board 40 and the printed circuit board 20, and the flexible printed circuit board 40 may be extended to the position where the connecting portion 70 is placed.

As another example, the flexible printed circuit board 40 may extend to the overlapping area OA of the printed circuit board 20 but may be connected to the printed circuit board 20 at a location relatively far from the display panel 10. In this case, the connecting portion 70 is placed in a middle portion of the flexible printed circuit board 40 and may be connected to the printed circuit board 20.

Below, a method of manufacturing a display device according to an example embodiment will be described. For convenience of explanation, below, the same content as previously described for the display device or content that can be easily applied by a person having ordinary knowledge in the technical field to which the present disclosure belongs will be omitted or briefly described.

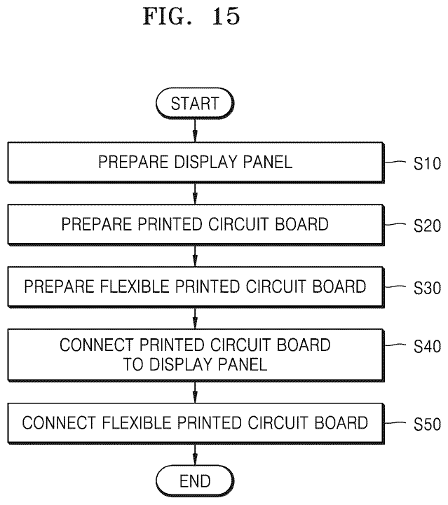

FIG. 15 is a flowchart for explaining a method of manufacturing a display device according to an example embodiment.

Referring to FIG. 15, a method of manufacturing a display device 1 according to an example embodiment may include preparing a display panel 10 (S10), preparing a printed circuit board 20 (S20), preparing a flexible printed circuit board 40 (S30), connecting S0 the printed circuit board 20 to the display panel 10 (S40), and connecting the flexible printed circuit board 40 (S50).

Preparing a display panel 10 (S10) may be preparing a display panel 10, which includes a first surface 13 and a second surface 14.

The display panel 10 may include a substrate 100, a thin film transistor TFT, and a sealing member 300. Here, the substrate 100, the thin film transistor TFT, and the sealing member 300 may be the substrate 100, the thin film transistor TFT, and the sealing member 300 described with reference to FIGS. 1 to 5. Additionally, the display panel 10 may include additional components to perform other functions.

Preparing a display panel 10 (S10) may include disposing the thin film transistor TFT on the substrate 100 and disposing the sealing member 300 on the thin film transistor TFT.

In an example embodiment, disposing the sealing member 300 on the thin film transistor TFT may be disposing the sealing member 300 such that at least a portion of the thin film transistor TFT is exposed. For example, disposing the sealing member 300 may be forming the sealing member 300 to have an area smaller than an area of the thin film transistor TFT.

In an example embodiment, preparing a display panel 10 (S10) may include forming a convex portion 11.

The convex portion 11 may be a portion formed by protruding in one direction from one side of the display panel 10. For example, the convex portion 11 may protrude along a direction in which the flexible printed circuit board 40 extends. The concave portion 12 may mean a space formed adjacent to the convex portion 11 defined by forming the convex portion 11.

In an example embodiment, the convex portion 11 may be a portion where the substrate 100 and the thin film transistor TFT protrude. Accordingly, a distance from the sealing member 300 to an end of the display panel 10 may be longer at a portion where the convex portion 11 is formed than at a portion where the concave portion 12 is formed.

Preparing a printed circuit board 20 (S20) may be preparing a printed circuit board 20 including an upper surface 21 and a lower surface 22.

Preparing S20 a printed circuit board 20 may include mounting at least one component 30 onto the printed circuit board 20.

In an example embodiment, the component 30 may be placed on the lower surface 22 of the printed circuit board 20. Here, the lower surface 22 may refer to one surface of the printed circuit board 20 that is connected to the display panel 10.

Preparing a flexible printed circuit board 40 (S30) may be preparing a flexible printed circuit board 40 that will electrically connect the display panel 10 and the printed circuit board 20.

Connecting the printed circuit board 20 (S40) to the display panel 10 (S40) may be connecting the printed circuit board 20 with component 30 mounted thereon to the display panel 10.

As one example, connecting the printed circuit board 20 to the display panel 10 (S40) may be connecting the printed circuit board 20 to the display panel 10 such that the first surface 13 of the display panel 10 and at least a portion of the lower surface 22 of the printed circuit board 20 overlap. The printed circuit board 20 is arranged so that at least a portion thereof overlaps the first surface 13 of the display panel 10 and may extend in a direction away from the display panel 10. Here, a portion of the printed circuit board 20 extending away from the display panel 10 may not overlap with the display panel 10.

Accordingly, the printed circuit board 20 may include an overlapping area OA that overlaps the display panel 10 and a non-overlapping area NOA that does not overlap the display panel 10. Therefore, the printed circuit board 20 may be connected to the display panel 10 while overlapping it by the amount of the overlapping area.

In an example embodiment, at least one component 30 may be placed in the non-overlapping area NOA. That is, the overlapping area OA of the lower surface 22 of the printed circuit board 20 may be connected to the display panel 10, and the component 30 may be placed on the non-overlapping area NOA.

Connecting the flexible printed circuit board 40 (S50) may be connecting the flexible printed circuit board 40 to the printed circuit board 20 and the display panel 10.

Connecting the flexible printed circuit board 40 (S50) may include connecting the flexible printed circuit board 40 to the second surface 14 of the display panel 10 and the upper surface 21 of the printed circuit board 20 while bending at least a portion of the flexible printed circuit board 40. Here, the flexible printed circuit board 40 may be bent away from the display panel 10.

By bending the flexible printed circuit board 40, a space 60 may be provided between the display panel 10 and the bent portion of the flexible printed circuit board 40. For example, one side of the flexible printed circuit board 40 may be connected to the second surface 14 of the display panel 10, extended in a direction away from the display panel 10, bent in a direction toward the printed circuit board 20, and extended toward the upper surface 21 of the printed circuit board 20 to be connected to the upper surface 21 of the printed circuit board 20.

Accordingly, as the flexible printed circuit board 40 extends away from the display panel 10, the space 60 may be provided between the display panel 10 and the bent portion of the flexible printed circuit board 40.

As an optional example embodiment, one or component 30 may be placed in the non-overlapping area NOA of the lower surface 22 of the printed circuit board 20, and at least component may be placed inside the space 60.

Therefore, the non-overlapping area NOA of the lower surface 22 of the printed circuit board 20 may be placed to overlap the space 60, and the component 30 may be placed in the non-overlapping area NOA.

Specifically, the printed circuit board 20 is connected to the display panel 10 with the component 30 mounted on the lower surface 22 thereof. Thus, the component 30 may be placed in the non-overlapping area NOA. In addition, the flexible printed circuit board 40 is connected after the printed circuit board 20 is connected to the display panel 10. Thus, the component 30 may be placed on the inside of the space.

In an example embodiment, connecting S50 the flexible printed circuit board 40 may be connecting the flexible printed circuit board 40 such that the exposed portion of the thin film transistor TFT overlaps at least a portion of the flexible printed circuit board 40.

In an example embodiment, connecting the flexible printed circuit board 40 (S50) may include pressing the printed circuit board 20 and the flexible printed circuit board 40.

In an example embodiment, a connecting portion 70 may be further arranged between the printed circuit board 20 and the flexible printed circuit board 40. The connecting portion 70 may be a portion that physically and electrically connects the printed circuit board 20 and the flexible printed circuit board 40.

As an optional example embodiment, the connecting portion 70 may be a connecting film. That is, the printed circuit board 20 and the flexible printed circuit board 40 may be connected in a film on board (FOB) method. Accordingly, the connecting portion 70 may be placed between the printed circuit board 20 and the flexible printed circuit board 40 to perform the function of the driving circuit.

Therefore, the printed circuit board 20 and the flexible printed circuit board 40 may be connected in the FOB manner by pressing the printed circuit board 20 and the flexible printed circuit board 40.

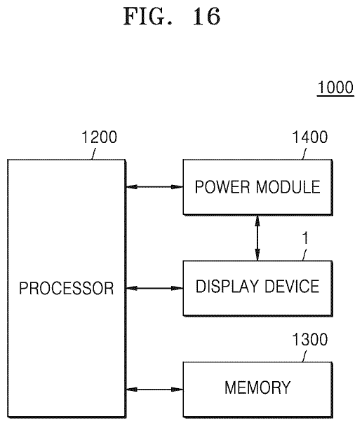

FIG. 16 is a block diagram of an electronic device according to an example embodiment.

Referring to FIG. 16, the electronic device 1000 may include a display device 1, a processor 1200, a memory 1300, and a power module (or alternatively, power supply) 1400.

The display device 1 may receive data from the processor 1200 and provide visual information. The display device 1 may be the display device 1 according to one of the example embodiments described above.

The processor 1200 may include at least one of a central processing unit (CPU), an application processor (AP), a graphic processing unit (GPU), a communication processor (CP), an image signal processor (ISP), or a controller. For example, the processor 1200 can operate by executing at least one program.

The memory 1300 may store data information necessary for the operation of the processor 1200 or display device 1. For example, the memory 1300 may store the at least one program. Image data signals and/or input control signals are transmitted to the display device 1 when the processor 1200 executes an application stored in the memory 1300, and the display device 1 may process the received signals and output image information through the display screen.

The power module 1400 may include a power supply module such as a power adapter or a battery device, and a power conversion module that converts power supplied by the power supply module to generate power required for operation of the electronic device 1000. For example, power module 1400 may supply power to the display device 1.

At least one of the components of the electronic device 1000 described above may be included in the display device 1 according to one of the example embodiments described above. Additionally, some of individual modules that are functionally included within a single module may be included within the display device 1 and others may be provided separately from the display device 1.

Any functional blocks shown in FIG. 16 and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

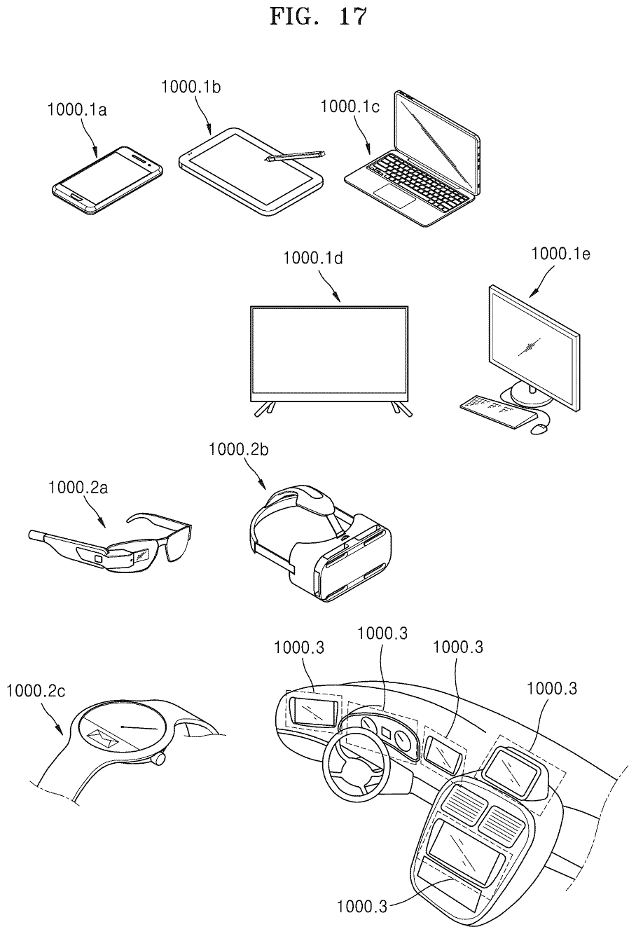

FIG. 17 is a schematic diagram of electronic devices according to various example embodiments.

Referring to FIG. 17, various electronic devices to which the display device according to example embodiments are applied may include not only electronic devices for displaying images such as smart phones 1000.1a, tablet personal computers 1000.1b, laptops 1000.1c, TVs 1000.1d and desk monitors 1000.1e, but also wearable electronic devices including display devices such as smart glasses 1000.2a, head-mounted displays 1000.2b and smart watches 1000.2c, electronic devices for vehicles 1000.3 including display devices such as center information displays (CIDs) arranged on instrument panels, center fascias and dashboards of automobiles, and room mirror displays, or the like.

In this way, in the case of the display devices, the methods of manufacturing the display device, and the electronic devices including the display device, the component 30 is placed in the dead space created by the connection between the components forming the display device, so that the dead space may be efficiently utilized and/or the overall thickness of the device may be reduced.

In addition, in the case of the display device, the methods of manufacturing the display device and the electronic devices including the display device, a part of the exposed portion of the display panel 10 is covered by the printed circuit board 20, the flexible printed circuit board 40, or the like. Thus, damage to the display panel 10 due to external impact is prevented or reduced.

However, it is not limited to this and may have various other effects as explained above.

Display devices capable of improving space utilization within the display device may be provided.

However, these effects are merely examples and the effects of the present disclosure are not limited thereto.

Each of the example embodiments described above can be implemented independently, but it goes without saying that the structure of each example embodiment can be applied in combination to other example embodiments.

Although some example embodiments have been described with reference to the drawings, they are merely examples, and those skilled in the art will understand that various modifications and equivalent other example embodiments are possible therefrom. Accordingly, the technical protection scope of example embodiments should be determined by the technical idea of the appended claims.

The specific implementations described in the example embodiments are merely examples and do not limit the scope of example embodiments in any way. Also, if there is no specific mention of something such as “essential”, “important”, it may not be a required or desired component.

The use of the term “the” and similar referential terms in the specification of example embodiments (especially in the claims) may refer to both the singular and the plural. In addition, if a range is described in an example embodiment, it is considered that the inventive concepts include an individual value that falls within the range (unless otherwise stated), and it is the same as describing each individual value that constitutes the range in the detailed description. Finally, unless there is an explicit description of the order or sequence of steps constituting a method according to an example embodiment, the steps may be performed in any suitable order. The example embodiments are not necessarily limited to the order in which the above steps are described. Any use of examples or example terms in the example embodiments is merely intended to elaborate the example embodiments and is not intended to limit the scope of example embodiments, unless otherwise defined by the claims. Furthermore, those skilled in the art will appreciate that various modifications, combinations and variations can be made according to design conditions and factors within the scope of the appended claims or their equivalents.

What is claimed is:

1. A display device comprising:
a display panel comprising a first surface and a second surface opposite to the first surface;
a printed circuit board including a third surface and a fourth surface opposite to the third surface, at least part of the third surface overlapping and connected to the first surface of the display panel, the printed circuit board extending in a direction away from the display panel;
at least one component on the printed circuit board; and
a flexible printed circuit board connected to the second surface of the display panel and the fourth surface of the printed circuit board, the flexible printed circuit board being bent in a direction away from the display panel to provide a space between the display panel and a bent portion.

2. The display device of claim 1, wherein
the display panel comprises
a substrate,
a thin film transistor on the substrate, and
a sealing member on the thin film transistor and exposing at least a portion of the thin film transistor, and
the flexible printed circuit board is connected to an exposed portion of the thin film transistor.

3. The display device of claim 1, wherein the display panel comprises a convex portion protruding in a direction in which the flexible printed circuit board extends.

4. The display device of claim 3, wherein the printed circuit board has a width wider than a width of the convex portion.

5. The display device of claim 3, wherein the printed circuit board completely covers the convex portion.

6. The display device of claim 3, wherein a plurality of convex portions including the convex portion are along one side of the display panel.

7. The display device of claim 1, further comprising:
a hinge adjacent to the printed circuit board and on one side of the display panel.

8. The display device of claim 7, wherein the hinge overlaps at least one of a part of one surface of the display panel or at least a part of one surface of the printed circuit board.

9. The display device of claim 1, wherein
the printed circuit board comprises an overlapping area that overlaps the display panel and a non-overlapping area that does not overlap the display panel, and
the component is in the non-overlapping area.

10. The display device of claim 1, wherein the component is placed on the third surface of the printed circuit board.

11. The display device of claim 1, further comprising:
a connecting portion between the printed circuit board and the flexible printed circuit board.

12. The display device of claim 11, wherein the connecting portion is on an opposite side of the component with respect to the printed circuit board.

13. A method of manufacturing a display device, the method comprising:
preparing a display panel comprising a first surface and a second surface opposite to the first surface;
preparing a printed circuit board including at least one component arranged thereon and comprising a third surface and a fourth surface opposite to the third surface;
preparing a flexible printed circuit board;
connecting the printed circuit board to the display panel such that the third surface of the printed circuit board is connected to the first surface of the display panel and at least a portion of the third surface of the printed circuit board overlaps the first surface of the display panel; and
connecting the flexible printed circuit board to the second surface of the display panel and the fourth surface of the printed circuit board while being bent in a direction away from the display panel to form a space between the display panel and a bent portion of the printed circuit board.

14. The method of claim 13, wherein
the preparing the display panel comprises
disposing a thin film transistor on a substrate, and
disposing a sealing member on the thin film transistor while exposing at least a portion of the thin film transistor, and
the connecting the flexible printed circuit board comprises connecting an exposed portion of the thin film transistor and at least a portion of the flexible printed circuit board overlapping each other.

15. The method of claim 13, wherein the preparing the display panel comprises forming a convex portion protruding in a direction in which the flexible printed circuit board extends.

16. The method of claim 13, wherein the preparing the printed circuit board includes mounting the component on the third surface of the printed circuit board.

17. The method of claim 13, wherein
the printed circuit board comprises an overlapping area that overlaps the display panel and a non-overlapping area that does not overlap the display panel, and
the preparing the printed circuit board includes mounting the component in the non-overlapping area.

18. The method of claim 13, wherein the preparing the printed circuit board includes placing the component inside the space.

19. The method of claim 13, wherein the connecting the flexible printed circuit board further comprises pressing the printed circuit board and the flexible printed circuit board.

20. An electronic device comprising:
a memory configured to store at least one program;
a processor configured to execute the at least one program;
a display device configured to receive data from the processor and provide visual information; and
a power supply configured to supply power to the display device,
wherein the display device comprises
a display panel comprising a first surface and a second surface opposite to the first surface,
a printed circuit board including a third surface and a fourth surface opposite to the third surface, at least part of the third surface overlapping and connected to the first surface of the display panel, the printed circuit board extending in a direction away from the display panel,
at least one component on the printed circuit board, and
a flexible printed circuit board connected to the second surface of the display panel and the fourth surface of the printed circuit board, the flexible printed circuit board being bent in a direction away from the display panel to provide a space between the display panel and a bent portion.
